(19) United States
(12) Patent Application Publication
(10) Pub. No.: US 2004/0057548 A1
(43) Pub. Date: Mar. 25, 2004

(54) Quasi-synchronous multi-stage event synchronization apparatus

(75) Inventors: Jen-Pin Su, Han-San (TW); Tze-Hsiang Chao, San-Ming District (TW); Tsan-Hwi Chen, HsinChu City (TW)

Correspondence Address: LOWE HAUPTMAN GOPSTEIN GILMAN & BERNER, LLP, Suite 310, 1700 Diagonal Road, Alexandria, VA, 22314, US

(73) Assignee: SILICON INTEGRATED SYSTEM CORP.

(21) Appl. No.: 10/253,820

(22) Filed: Sep. 25, 2002

(51) Int. Cl. H03D 3/24; H04L 7/00

(52) U.S. Cl. 375/376; 375/356

(57) ABSTRACT

The present invention relates to a quasi-synchronous multi-stage event synchronization apparatus by a phase lock loop (PLL) control circuit and a quasi-synchronous multi-stage synchronizer to tolerate clock uncertainty and speed up the synchronizing process between the asynchronous digital circuits from producing-end to consuming-end in the computer system. The phase lock loop (PLL) control circuit generates a pair of well-controlled clocks, PDU_CLK, CSM_CLK, assigned to producing-end and consuming-end and a pair of clock phase indicating signals, PDU_SYNC_PULSE, CSM_SYNC_PULSE, associated with the pair of well-controlled clocks. The quasi-synchronous multi-stage synchronizer routes the series of sync events into a synchronization stage with minimal synchronization delay from producing-end to consuming-end.

### BACKGROUND OF THE INVENTION

1. Field of the Invention

The present invention relates to a quasi-synchronous multi-stage event synchronization apparatus used in the computer-electronics system, and particularly to a quasi-synchronous multi-stage event synchronization apparatus by the sync event routing of the quasi-synchronous multi-stage synchronizer and the phase control of the phase lock loop (PLL) control circuit to tolerate clock uncertainty and speed up the synchronizing process between the asynchronous digital circuits from producing-end to consuming-end in the computer (PC) system, and increase the performance and reliability of the computer-electronics system.

2. Description of Related Art

There are several clock sources in the conventional electronics system, such as computer system. For example, there are three different clock sources for CPU, memory and I/O devices in the personal computer (PC) system. It is necessary to synchronize the control signals and/or data among these asynchronous digital circuits of the different clock sources by a synchronizer. Even though the working frequency on the both ends is the same and derive from individual clock sources, some uncertainties in the transfer of control signals and/or data still exist between the producing-end and the consuming-end of the asynchronous digital circuits mentioned above.

In general, there are three major parts in an asynchronous logic. They are a producing logic; a consuming logic; and a synchronizer used to transform synchronously the events from the producing-end to the consuming-end. As shown in FIG. 1, it's the responsibility for synchronizer to synchronize the signal D2 from PDU_CLK to CSM_CLK clock domain and generate a corresponding signal Q1 synchronous to CSM_CLK clock domain. Then, the signal Q2 is sampled safely by any associated component 12 clocked by CSM_CLK clock. There are many schemes and structures of synchronizer to be disclosed. An exemplary synchronizer is shown as FIG. 2, the desired synchronized signal D1 is clocked by PDU_CLK clock at J-K F/F 20 that outputs a signal S1 also synchronous to PDU_CLK clock. And the signal S1 will be sampled by CSM_CLK clock at D- F/F 21 that generates an output signal S2. Similarly, the signal S2 is sampled by CSM_CLK clock at D- F/F 22 and generates an output signal S3. Finally, the synchronizer will output the signal Q, i.e., logical exclusive-OR 23 result of the signal S2 and S3.

As stated above, the responsibility of this kind of synchronizer called as event synchronizer is to pass a desired synchronized event from producing-end to consuming-end. As shown in FIG. 3, the synchronization latency is defined as Tsyncdly, the elapsed time from signal S1 to Q1, which will cause the synchronized event Q1 to not be sampled until Tc1. However, when we analyze in details about the origination of Tsyncdly, it can find out that the synchronization is accomplished by clocking the signal S1 and generates a corresponding signal S2 synchronous to CSM_CLK clock. So, the clock phase difference between PDU_CLK and CSM_CLK clocks will dominate the amount of latency. If the signal S1 can be passed directly, not waiting to clocking by CSM_CLK clock, and the synchronized output signal Q1 is generated with enough setup time budget to the component 12 at CSM_CLK domain, the synchronization latency will be minimized as shown in FIGS. 4 & 5. In FIG. 5, the synchronized signal Q1 will be sampled at Tc0 instead of Tc1 as the above synchronizer.

As stated above, the major purpose of quasi-synchronization is to minimize the synchronization latency. Its basic concept is to pass directly the desired synchronized event S1 from PDU_CLK to CSM CLK clock domain, other than clocked by CSM_CLK clock. But there is a limitation that the passed synchronized event Q1 must reserve timing budget enough to be collapsed by the following logic and consequently meet the setup and hold time requirement of clocked component 12. However, the reserved timing budget will be dominated by the clock phase difference of PDU_CLK and CSM_CLK. As shown in FIG. 6, the passed synchronized event will cause the signal Q2 not to meet the setup time requirement of clocked component 12. Therefore, the quasi-synchronization approach must rely on clock phase relationship between PDU_CLK and CSM_CLK and the reserved timing budget associated with the consuming logic cloud 14 and clocked component 12. According to these information, it can decide which one desired synchronized event D2 can be directly passed or not (must be clocked by CSM_CLK). In order to provide the capability of directly pass and clocked synchronization, the conceptual quasi-synchronizer is constructed by multiple stage structure, and it basically comprises the clocked synchronizer and the direct-pass synchronizer.

### SUMMARY OF THE INVENTION

The object of the present invention is to eliminate the synchronization delay of a synchronizer in the transfer of systems and make the system in quasi-synchronous state to execute functions of the system more efficiently and steadily. To reach the above objective, this present invention provides a quasi-synchronous multi-stage event synchronization apparatus, as shown in FIG. 7. The apparatus is comprised of a PLL control circuit and a quasi-synchronous multi-stage synchronizer. The PLL control circuit will offer a set of well-controlled clock signals, i.e., PDU_CLK and CSM_CLK, based on the predetermined clock frequency ratio. The quasi-synchronous multi-stage synchronizer will route sync event to an appropriate synchronization stage and synchronize it from PDU_CLK to CSM_CLK domain in order to minimize the overall synchronization delay by the well-controlled clock signals and sync phase.

The PLL control circuit offers a pair of well-controlled (PDU_CLK and CSM_CLK) clock signals and makes PDU_CLK and CSM_CLK to be kept in the specific in-phase relationship. In addition, a balance clock approach is used to keep the above specific in-phase relationship between the tree and the leaf components. The PLL control circuit also produces a pair of clock phase indicator signals (PDU_SYNC_PHASE and CSM_SYNC_PHASE) to indicate at which in-phase now.

As shown in FIG. 10, the quasi-synchronous multi-stage synchronizer is comprised of a synchronization unit, a routing unit and an in-phase mask generator. In FIG. 11, the multi-stage synchronization unit comprises GEN_CLKED_SYNR, GEN_THRU_SYNR and INPH_THRU_SYNR stage groups. Basically, the synchronization delay of GEN_THRU_SYNR and INPH_THRU_SYNR stage groups is shorter than GEN_CLKED_SYNR stage group, but the setup time budget of GEN_CLKED_SYNR is larger than GEN_THRU_SYNR and INPH_THRU_SYNR stage groups. The setup time budget is reserved for the time domain of subsequent logic behind of the synchronizer.

The formulaic routing rules are proposed in the specification of present invention, it provides an efficient method to get easily and systematically the optimal routing path with minimal synchronization delay.

Base on the idea described above, the present invention relates to a quasi-synchronous multi-stage event synchronization apparatus for transferring a series of synchronized event from producing-end to consuming-end that operate at different phases, at the same frequency or at different frequencies, comprises a phase lock loop (PLL) control circuit for generating a pair of well-controlled clocks assigned and distributed to producing-end and consuming-end and a pair of clock phase indicating signals associated with the above a pair of well-controlled clocks, and a quasi-synchronous multi-stage synchronizer for routing a series of sync events into an appropriate synchronization stage with minimal synchronization delay and synchronizing from producing-end to consuming-end.

Base on the idea aforementioned, wherein said phase lock loop (PLL) control circuit further comprises a pair of phase lock loop components for locking the clock phases, making the clocks of producing-end and consuming-end to be kept at in-phase relationship, and providing the pair of clock phase indicating signals; a group of I/O buffers for providing a input path to convert a external clock source into a internal silicon chip and two clock feedback paths for the clocks at producing-end and consuming-end; and a latch component for keeping a predetermined value of clock frequency ratio after the pair of phase lock loop components are reset.

Base on the idea described above, wherein the quasi-synchronous multi-stage synchronizer further comprises a synchronization unit for synchronizing the series of routed sync events by the synchronization stage from producing-end to consuming-end; a routing unit for deciding and routing the series sync event into the synchronization stage in the synchronization unit; and an in-phase mask generator for generating a synchronized event mask signal at a in-phase sync phase.

Base on the idea aforementioned, wherein the synchronization unit further comprises a general clocked synchronizer stage group for converting a plurality of routed sync events into a plurality of synced events that can be safely sampled by the clock of consuming-end; a general pass-through synchronizer stage group for converting a plurality of routed sync events into a plurality of synced events that can be safely sampled by the clock of consuming-end; and an in-phase pass-through synchronizer stage group for converting a plurality of routed sync event into a plurality of synced events that can be safely sampled by the clock of consuming-end.

Base on the idea described above, wherein the routing unit further comprises a sync phase generator for generating a sync phase indicator signal of said producing-end; and a sync stage switcher for routing the series of sync events and dispatching the sync events into the synchronization stage in the synchronization unit.

### BRIEF DESCRIPTION OF THE DRAWING

The invention will be better understood and objects other than those set forth above will become apparent when consideration is given to the following detailed description thereof. Such description makes reference to the annexed drawings wherein:

FIG. 1 is a schematic diagram showing the conventional asynchronous logic;

FIG. 2 is a schematic circuit showing the conventional exemplary event synchronizer;

FIG. 3 is a timing chart of the conventional exemplary event synchronizer;

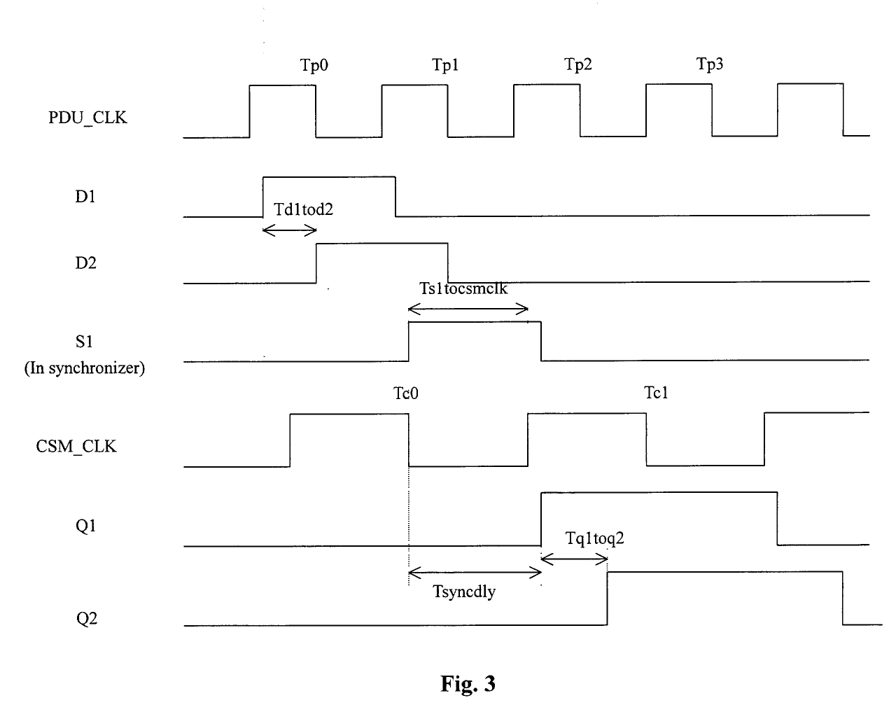

FIG. 4 is a schematic circuit showing the quasi-synchronous event synchronizer of the present invention;

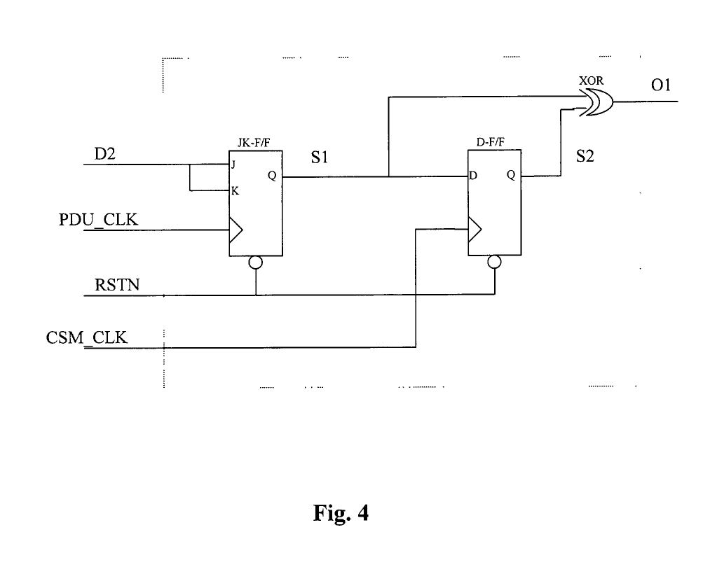

FIG. 5 is the first timing chart of the quasi-synchronous event synchronizer of the present invention;

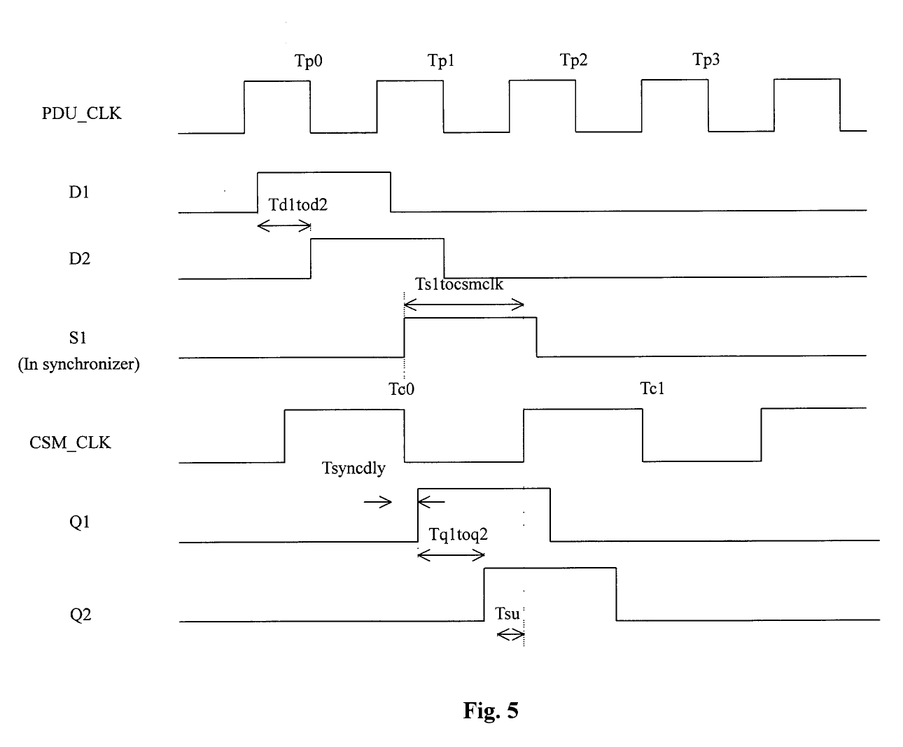

FIG. 6 is the second timing chart of the quasi-synchronous event synchronizer of the present invention;

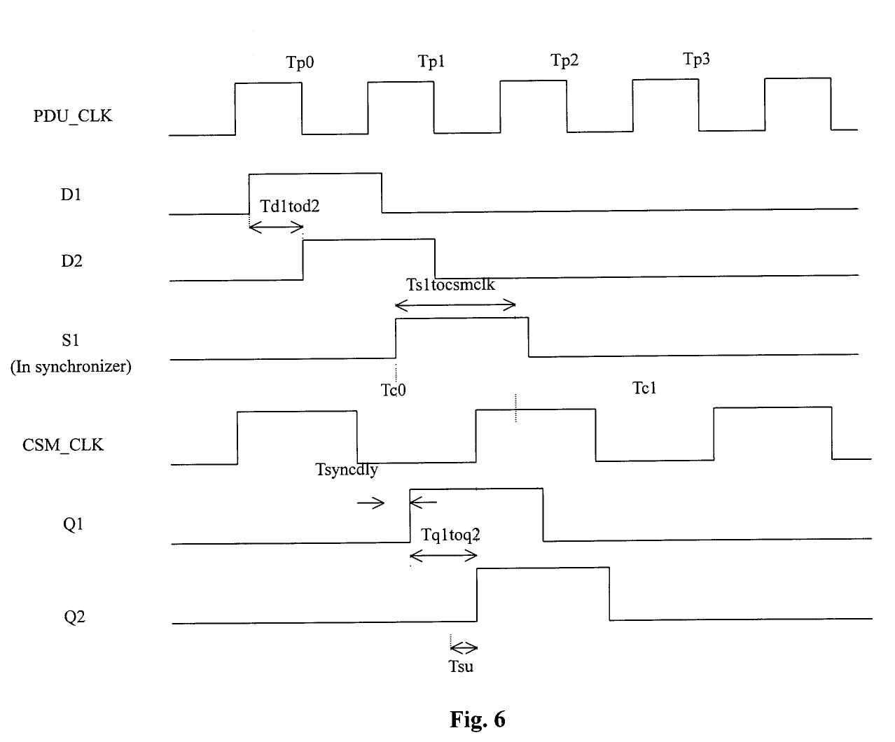

FIG. 7 is a schematic diagram showing the quasi-synchronous multi-stage event synchronization apparatus of the present invention;

FIG. 8 is the timing chart of the PLL control circuit of the present invention, wherein the clock frequency ratio (Fpdu_clk:Fcsm_clk)=4:3;

FIG. 9 is a schematic circuit showing the PLL control circuit of the present invention;

FIG. 10 is a schematic circuit showing the quasi-synchronous multi-stage synchronizer of the present invention;

FIG. 11 is a schematic circuit showing the synchronization unit of the present invention;

FIG. 12 is a schematic circuit showing the GEN_CLKED_SYNR of the present invention;

FIG. 13 is a schematic circuit showing the GEN_THRU_SYNR of the present invention;

FIG. 14 is a schematic circuit showing the INPH_THRU_SYNR of the present invention;

FIG. 15 is a schematic circuit showing the routing unit of the present invention;

FIG. 16 is the timing chart of an exemplary SYNC event through INPH_THRU_SYNR of the present invention, wherein the clock frequency ratio (Fpdu_clk:Fcsm_clk)=4:3.

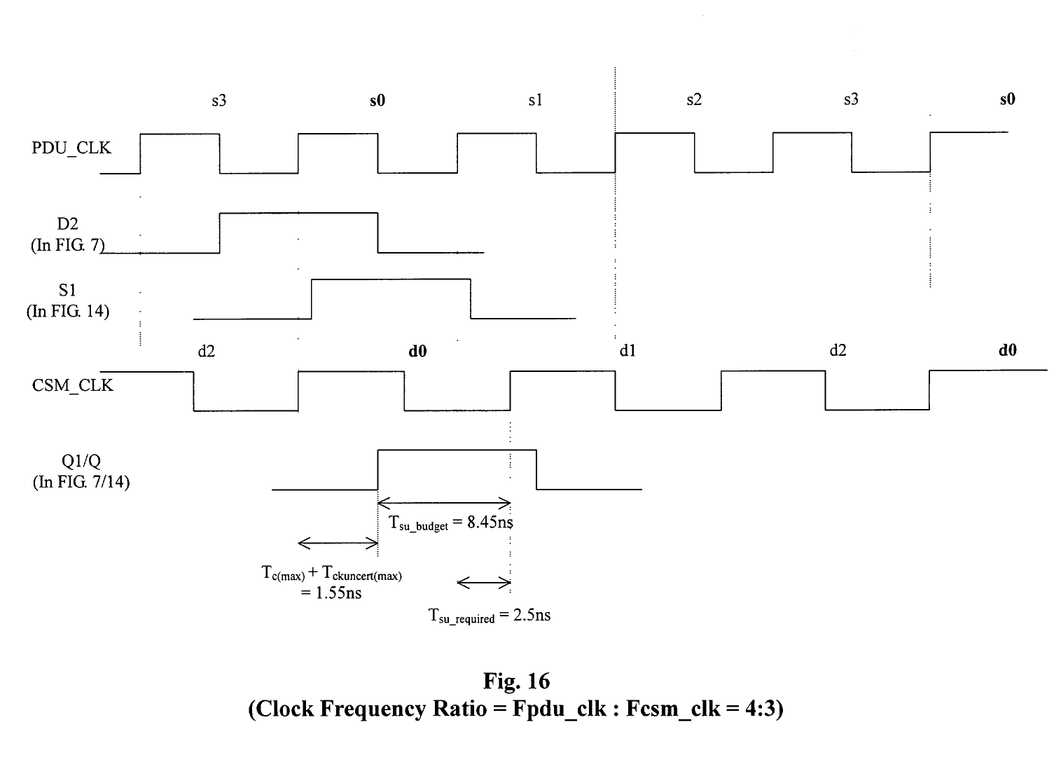

### DETAILED DESCRIPTION OF PREFERRED EMBODIMENT

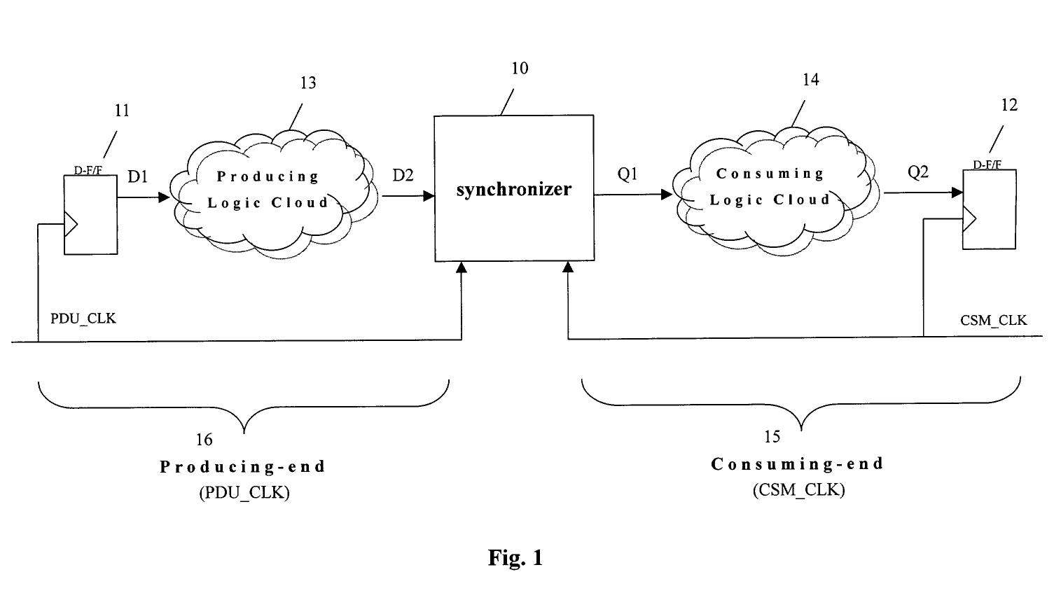

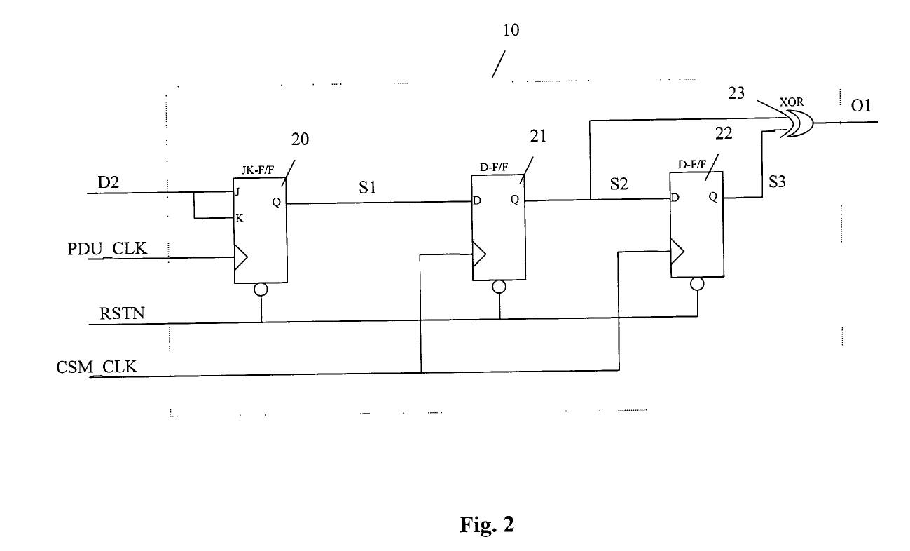

As shown in FIG. 1, it's the function of the synchronizer 10 to synchronize the signal D2 from PDU_CLK clock domain 16 to CSM_CLK clock domain 15, and generate simultaneously a corresponding signal Q1 to CSM_CLK clock domain 15. In other words, the output signal Q2 clocked by CSM_CLK clock can be safely sampled by D-F/F clock component 12. In FIG. 2, it shows the schematic circuit of an exemplary synchronizer 10. The desired synchronized signal D2 is clocked by PDU_CLK clock at J-K F/F 20 that output simultaneously a signal S1 also synchronized to PDU_CLK clock, then the signal S1 will be sampled by CSM_CLK clock at D- F/F 21 that generates an output signal S2. Similarly, the signal S2 will be sampled by CSM_CLK clock at D- F/F 22 that generates an output signal S3. Finally, the synchronizer 10 will output the signal Q1, a logic result of the signals S2 and S3 by exclusive OR 23.

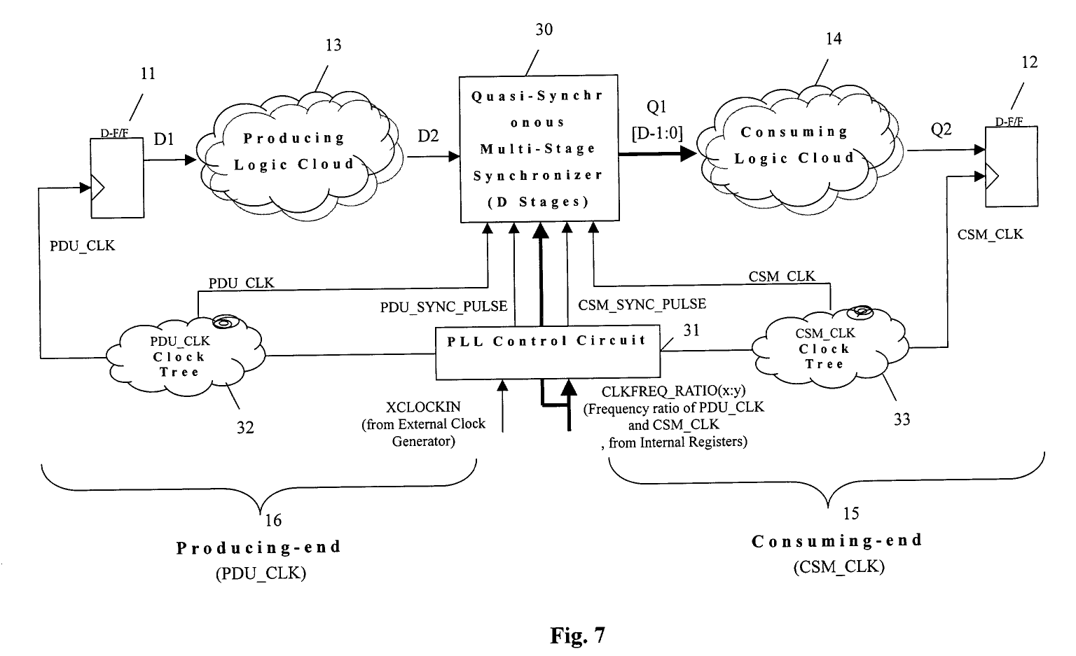

It is the schematic diagram of a quasi-synchronous multi-stage event synchronization apparatus according to the present invention as shown in FIG. 7, which comprises a quasi-synchronous multi-stage synchronizer 30 and a PLL control circuit 31. The PLL control circuit 31 generates four output signals (PDU_CLK, CSM_CLK, PDU_SYNC_PULSE, and CSM_SYNC_PULSE) and receives two input signals (XCLOCKIN and CLKFREQ_RATIO).

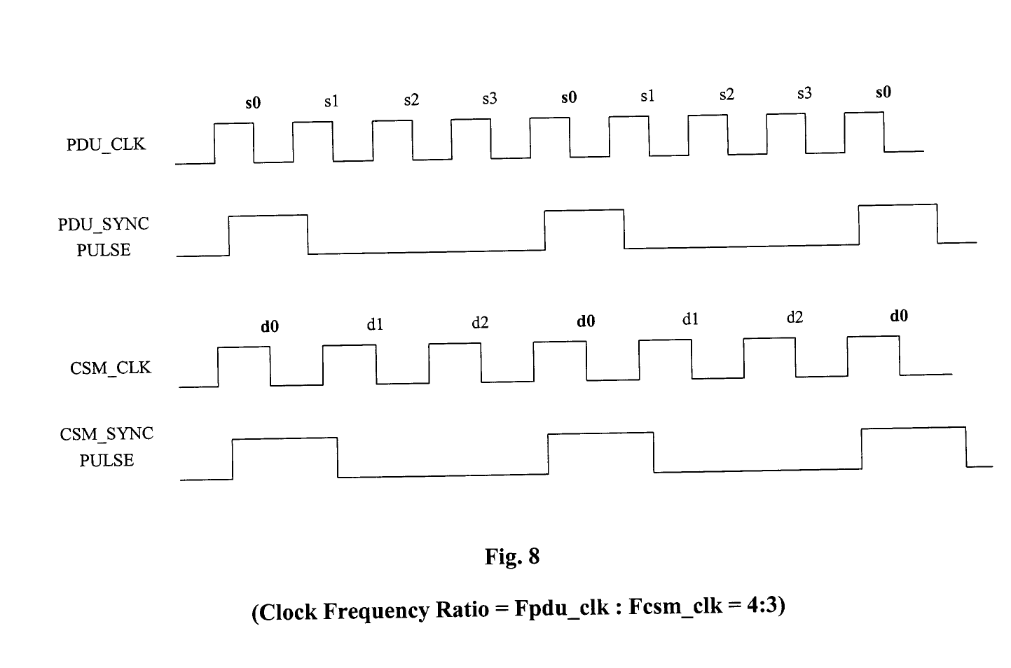

As shown in FIG. 8, it shows the timing relationship of the four output signals of the PLL control circuit 31 under the condition of CLKFREQ_RATIO (PDU_CLK:CSM_CLK) is set in 4:3, it implies that three times of PDU-CLK cycle time (Tpdu-clk) is equal to four times of CSM-CLK cycle time (Tcsm-clk). In addition, the PLL control circuit 31 will lock PDU_CLK and CSM_CLK in-phase at each time interval of the same Tin-phase. The first rising edge of PDU_CLK and CSM_CLK at each time interval of the same Tin-phase must be kept in-phase relationship. The PDU_SYNC_PULSE is asserted at the first cycle time (s0) of each Tin-phase time interval and synchronized to PDU_CLK domain. Similarly, the CSM_SYNC_PULSE is asserted at the first cycle time (d0) of each Tin-phase time interval and synchronized to CSM_CLK domain. According to the predetermined relationship of PDU_CLK and CSM_CLK controlled by the PLL control circuit 31, the quasi-synchronous multi-stage synchronizer 30 can transfer quickly and directly SYNC event D2 (shown in FIG. 7) at one specific cycle time of PDU_CLK, such as s0, s2 or s3 (shown in FIG. 8) and delay to transfer SYNC event D2 at other cycle times, such as s1 (shown in FIG. 8). This quasi-synchronization approach will minimize the overall synchronization latency.

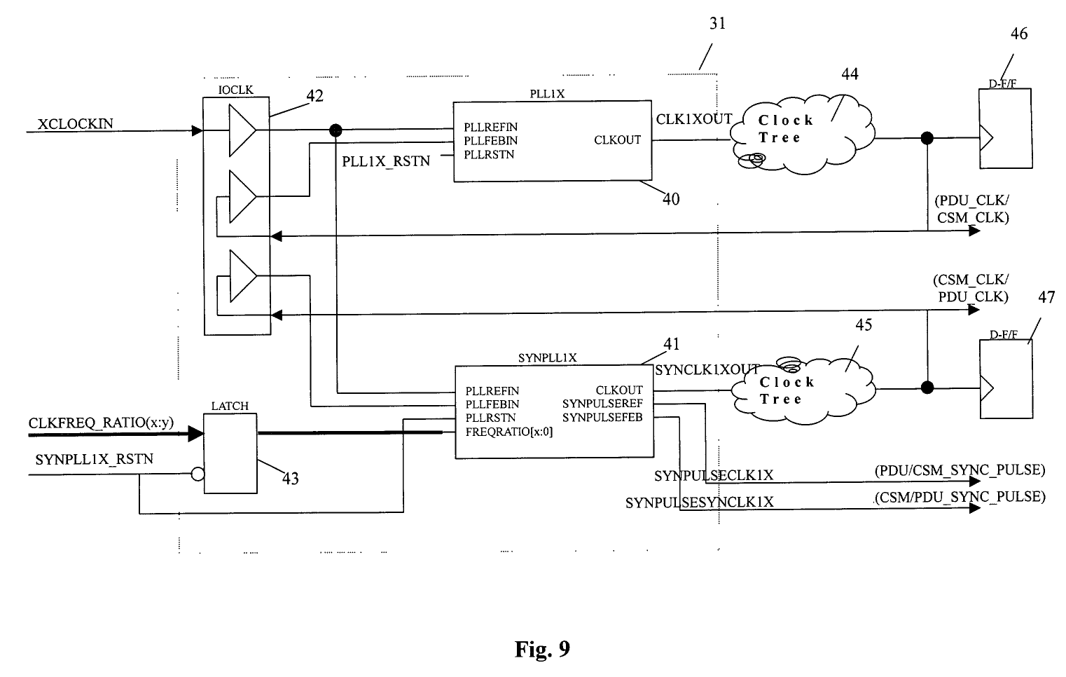

As shown in FIG. 9, it is the schematic circuit of the PLL control circuit 31 of the present invention. The I/OCLK 42 component, input/output buffer group, includes three individual clock I/O buffers, one is for the clock input of XCLOCKIN, another is for the clock feedback of PLL1X 40, and the other is for the clock feedback of SYNPLL1X 41. The purpose of clock feedback through I/O buffer is to compensate the I/O buffer delay and keep in-phase relationship between internal and external clocks. The component LATCH 43 is to provide a latch capability and keep a stable CLKFREQ_RATIO value after the reset of SYNPLL1X 41. The component PLL1X 40 in the PLL control circuit 31 is used to lock the phase of clock associated with CLK1XOUT and make the PLLREFIN and PLLFEBIN of PLL1X 40 to be kept in-phase. In addition, SYNPLL1X 41 will generate an output clock SYNCLK1XOUT according to its PLLREFIN and FREQRATIO inputs. The frequency ratio of CLK1XOUT and SYNCLK1XOUT is equal to the ratio indicated by the FREQRATIO, i.e., x:y. In FIG. 9, the leaf output signal of clock tree 44 can be designated as PDU_CLK or CSM_CLK in accordance with the synchronization, which depends on the direction from CLK1XOUT to SYNCLK1XOUT or from SYNCLK1XOUT to CLK1XOUT. If the leaf output signal of clock tree 44 is designated as PDU_CLK, the leaf output signal of clock tree 45 should be designated as CSM_CLK. Likewise, the SYNPULSECLK1X is designated as PDU_SYNC_PUSE and SYNPULSESYNCLK1X is designated as CSM_SYNC_PULSE. The clock tree 44 is a kind of balance tree and provides a balanced clock signal for any leaf D-F/F clock component 46. Similarly, the clock tree 45 is also a balance tree and provides a balanced clock signal for any leaf D-F/F clock component 47.

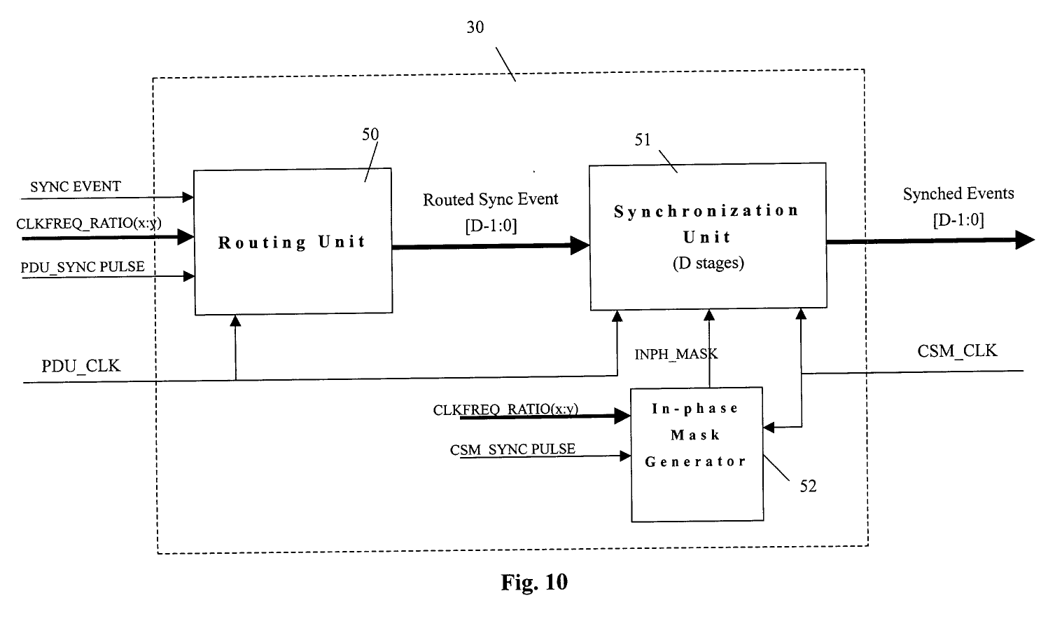

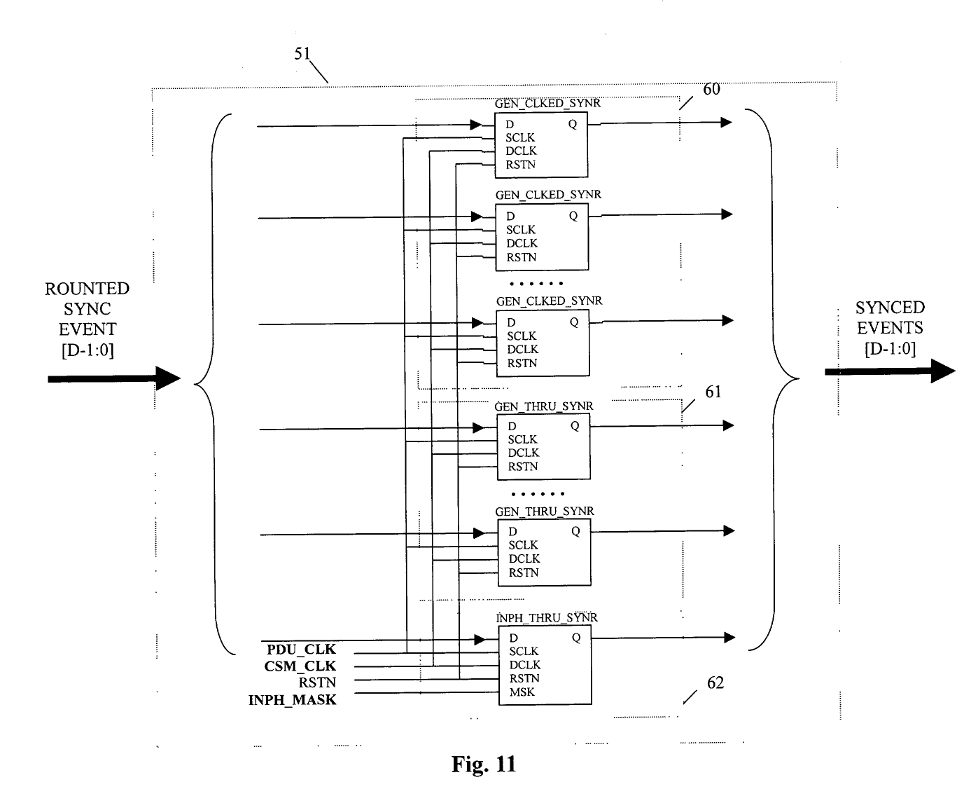

It's the schematic diagram of quasi-synchronous multi-stage event synchronizer 30 in FIG. 10, which comprises routing unit 50, synchronization unit 51, and in-phase mask generator 52. The synchronization unit 51 provides multiple synchronous stages to synchronize the routed SYNC event from PDU_CLK to CSM_CLK domain. As shown in FIG. 11, the synchronization unit is comprised of three multi-stage synchronizer groups, including a general clocked synchronizer (GEN_CLKED_SYNR) 60, a general pass-through synchronizer (GEN_THRU_SYNR) 61 and an in-phase pass-through synchronizer (INPH_THRU_SYNR) 62.

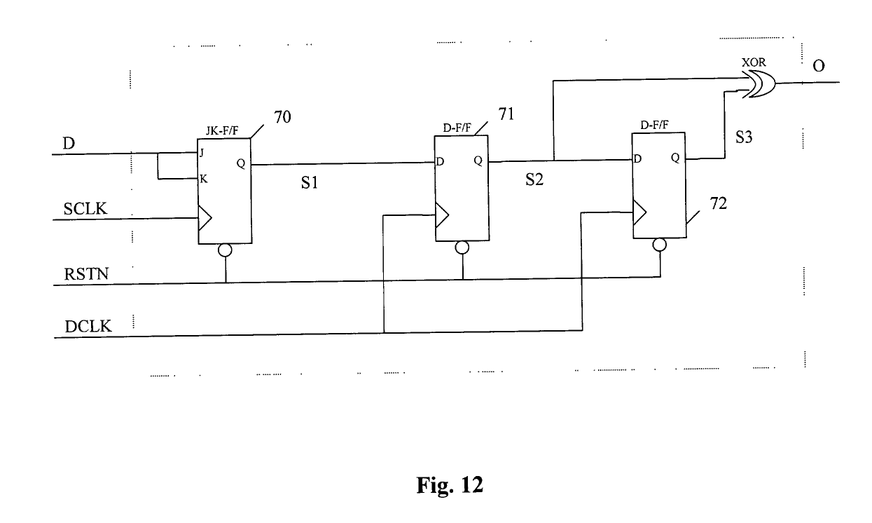

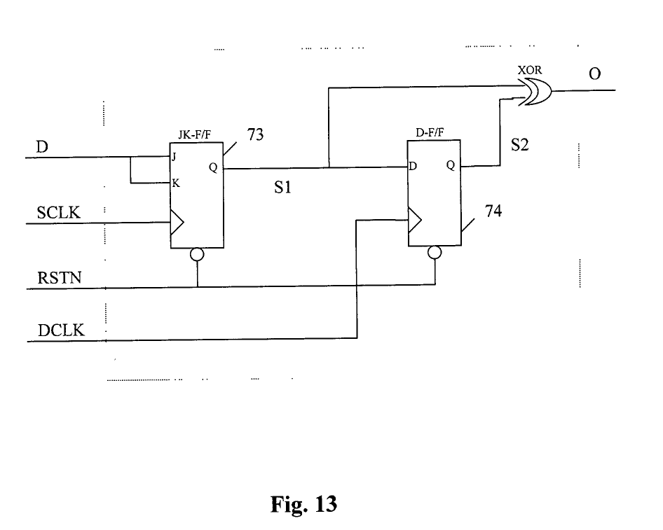

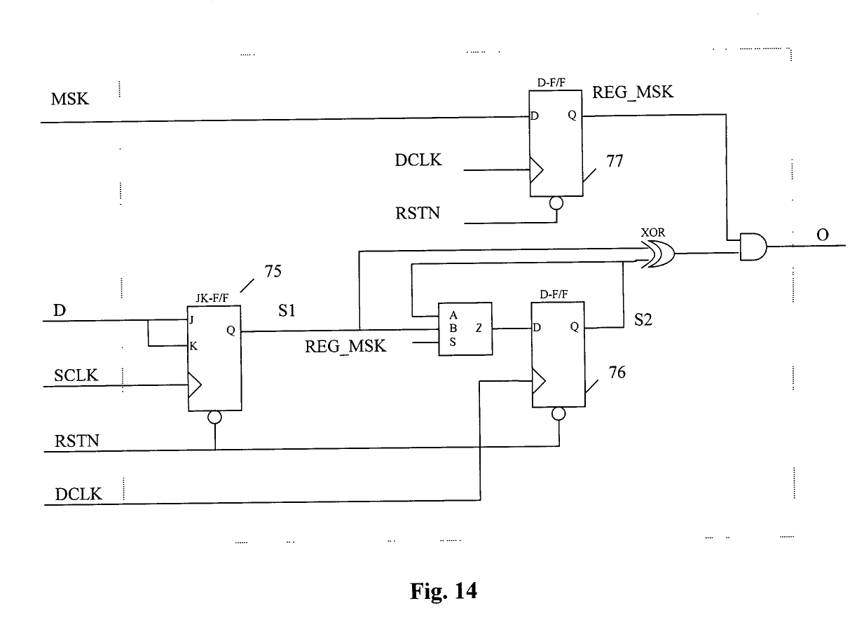

As shown in FIG. 12, it's the schematic circuit of a general clocked synchronizer (GEN_CLKED_SYNR) 60. It provides a safe synchronization stage with sufficient reserved setup-time budget but longer synchronization delay. It shows the schematic circuit of a general pass-through synchronizer (GEN_THRU_SYNR) 61 in FIG. 13. It provides a fast synchronization stage to transfer directly SYNC event from PDU_CLK to CSM_CLK domain, speeds up the response time of synchronization, and makes the synchronized event to be recognized rapidly at the consuming-end. As shown in FIG. 14, it is a special stage group called as in-phase pass-through synchronizer group (INPH_THRU_SYNR) 62, which is only comprised of a single INPH_THRU_SYNR component. It also provides a fast synchronization stage, but it's only utilized at the specific clock phase, i.e., at the in-phase clock cycle time as cycle time (s0) of PDU_CLK or cycle time (d0) of CSM_CLK in FIG. 8. Any routed SYNC event [D-1:0] is mapped into an appropriate synchronization stage and synchronized from PDU_CLK to CSM_CLK domain. The in-phase mask generator 52 will generate a signal to mask the synchronized event that synchronized through INPH_THRU_SYNR 62 at the specific in-phase phase. The mask signal can prevent INPH_THRU_SYNR 62 from generating a premature synchronized event and sampled by an unexpected edge of clock of the consuming-end 15.

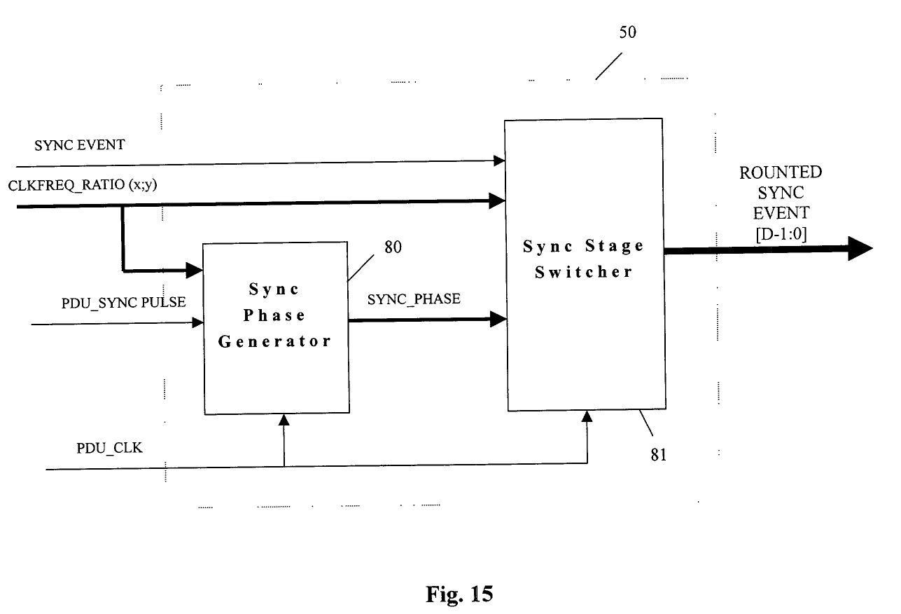

As shown in FIG. 15, it is a schematic circuit of the routing unit 51 that comprises a sync phase generator 80 and a sync stage switcher 81. The sync phase generator 80 is implemented by a module-X counter, which counts 0, 1, 2, . . . , X−1, 0, 1, 2, . . . in circular manner when CLKFREQ_RATIO is Fpdu_clk:Fcsm_clk (=X:Y) and is reset to 0 when input signal PDU_SYNC_PULSE is asserted. Then, it will output the encoded number to indicate whose phase is ongoing. The sync stage switcher 81 is used to switch the sync event to a synchronization stage based on CLKFREQ_RATIO, SYNC_PHASE and the cycle time of PDU_CLK and CSM_CLK.

How to select an appropriate synchronization stage for any sync event, it can be represented by the following routing rules:

If Tsu_budget(I)>=Tsu_required then

If I=0 then route to INPH_THRU_SYNR stage group

If I≠0 then route to GEN_THRU_SYNR stage group

Else (Tsu_budget(I)<Tsu_required) then

Route to GEN_CLKED_SYNR stage group

Note I:

1. Tsu_required: the elapsed time required to propagate through the subsequent combinational consuming logic cloud 14 (as shown in FIG. 7) and plus the setup and hold time requirement related to D-F/F clock component 12 (as shown in FIG. 7).

2. Tsu_budget (I): the set-up time budget reserved by a specific synchronization stage; I represents a specific sync phase at producing-end and may be 0, 1, 2, . . . , X−1 when CLKFREQ_RATIO is Fpdu_clk:Fcsm_clk (=X:Y).

3. Tsu_budget can be derived from the formula as follows:

Tsu_budget(0)=Tcsm_clk−Tc(max)−Tckuncert(max)

Tsu_budget(n)=mTcsm_clk−nTpdu_clk−Tc(max)−Tckuncert(max)

here, n=1, 2, . . . , X−1

m>=(nTpdu_clk+Tc(min)+Tckuncert(max))/Tcsm_clk

Note II:

1. Tcsm_clk: clock cycle time at consuming-end 15;

2. Tpdu_clk: clock cycle time at producing-end 16;

3. Tc: combinational delay in synchronizer, such as the clock-to-Q delay 71 (or 72) and XOR gate delay of GEN_CLKED_SYNR (as shown in FIG. 12);

4. Tckuncert: clock uncertainty factor, including clock jitter, clock skew and PLL phase error . . . etc.

5. The suffix “max” mentioned above represents the condition of the worst case.

6. The suffix “min” mentioned above represents the condition of the best case.

In order to make a good understanding of the above formula rules, a practical example is demonstrated as follows:

Supposition

1. The frequency of PDU_CLK clock=133 MHz

2. The frequency of CSM_CLK clock=100 MHz

3. CLKFREQ_RATIO=4:3

4. Tc(max)=1 ns

5. Tc(min)=0.5 ns

6. Tckuncert(max)=+/−0.55 ns (clock jitter=+/−0.2 ns; clock skew=+/−0.2ns; PLL phase error=+/−0.15 ns)

7. Tsu_required=2.5 ns

Based on the above supposition and the formula rules, Tsu_budget(x) for each sync phase can be derived as follows:

$$\begin{matrix}\begin{matrix}Tsu\_budget ( 0 ) = Tcsm\_clk - Tc ( max ) - Tckuncert ( max ) \\ = 10 - 1 - ( + 0.55 ) \\ = 8.45 ( ns )\end{matrix} \\ \begin{matrix}Tsu\_budget ( 1 ) = mTcsm\_clk - nTpdu\_clk - Tc ( max ) - Tckuncert ( max ) \\ = 10 - 7.5 - 1 - ( + 0.55 ) \\ = 0.95 ( ns )\end{matrix} \\ \begin{matrix}here , m >= ( nTpdu\_clk + Tc ( min ) + Tckuncert ( max ) ) / Tcsm\_clk \\ = ( 7.5 + 0.5 + ( - 0.55 ) ) / 10 \\ = 0.745\end{matrix} \\ So , m = 1. \\ \begin{matrix}Tsu\_budget ( 2 ) = mTcsm\_clk - nTpdu\_clk - Tc ( max ) - Tckuncert ( max ) \\ = 2 * 10 - 2 * 7.5 - 1 - ( + 0.55 ) \\ = 3.45 ( n s )\end{matrix} \\ \begin{matrix}here , m >= ( nTpdu\_clk + Tc ( min ) + Tckuncert ( max ) ) / Tcsm\_clk \\ = ( 2 * 7.5 + 0.5 + ( - 0.55 ) ) / 10 \\ = 1.495\end{matrix} \\ So , m = 2. \\ \begin{matrix}Tsu\_budget ( 2 ) = mTcsm\_clk - nTpdu\_clk - Tc ( max ) - Tckuncert ( max ) \\ = 3 * 10 - 3 * 7.5 - 1 - ( + 0.55 ) \\ = 5.95 ( ns )\end{matrix} \\ \begin{matrix}here , m >= ( nTpdu\_clk + Tc ( min ) + Tckuncert ( max ) ) / Tcsm\_clk \\ = ( 3 * 7.5 + 0.5 + ( - 0.55 ) ) / 10 \\ = 2.245\end{matrix} \\ So , m = 3.\end{matrix}$$

From the above result of Tsu_budget(I) (I=0, 1, 2, . . . , X−1; X=4) and the timing requirement of Tsu_required, the sync event happened at various sync phase at producing-end can be routed to an appropriate synchronization stage, as follows:

Sync phase (0) is routed to INPH_THRU_SYNR stage group when Tsu_budget(0) (=8.45 ns)>Tsu_reuired (=2.5 ns).

Sync phase (1) is routed to GEN_CLKED_SYNR stage group since Tsu_budget(0) (=0.95 ns)<Tsu_reuired (=2.5 ns).

Sync phase (2) is routed to GEN_THRU_SYNR stage group since Tsu_budget(0) (=3.45 ns)>Tsu_reuired (=2.5 ns).

Sync phase (3) is routed to GEN_CLKED_SYNR stage group since Tsu_budget(0) (=5.95 ns)>Tsu_reuired (=2.5 ns).

Note that multiple stages (D stages) in the same stage group need to be implemented to prevent subsequent sync event from be routed to a synchronizer that is processing a sync event synchronization. Here, D>=(Tcsm_clk+Tuncert)/Tpdu_clk; Tuncert represents the elapsed time by all uncertainty factors, such as clock. In practice, Tuncert is about 2.0 ns. As to the assignment of synchronization stage in a stage group, a simple round-robin rotation scheme is adopted.

The preferred embodiment described above is the better ones, which is to explain but limit the scope of the present invention; the scope of the present invention is defined by the claims described as follow. The variations and modifications according to the claims of the present invention should be included by the present invention.

What is claimed is:

1. A quasi-synchronous multi-stage event synchronization apparatus for synchronizing a series of sync events from a producing-end to a consuming-end, the clocks of said producing-end and said consuming-end operating at different phases, comprising:
a phase lock loop (PLL) control circuit for generating a pair of well-controlled clocks assigned to said producing-end and said consuming-end and a pair of clock phase indicating signals associated with said pair of well-controlled clocks; and
a quasi-synchronous multi-stage synchronizer for routing said series of sync events into a synchronization stage with minimal synchronization delay from said producing-end to said consuming-end.

2. The apparatus according to claim 1, wherein said the clocks of said producing-end and said consuming-end operate at different frequencies.

3. The apparatus according to claim 1, wherein said the clocks of said producing-end and said consuming-end operate at the same frequency.

4. The apparatus according to claim 1, wherein said phase lock loop (PLL) control circuit further comprises:
a pair of phase lock loop components for locking the clock phases, making the clocks of said producing-end and said consuming-end to be kept at in-phase relationship, and providing said pair of clock phase indicating signals;
a group of I/O buffers for providing a input path to convert a external clock source into a internal silicon chip and two clock feedback paths for the clocks at said producing-end and said consuming-end; and
a latch component for keeping a predetermined value of clock frequency ratio after said pair of phase lock loop components are reset.

5. The apparatus according to claim 1, wherein said quasi-synchronous multi-stage synchronizer further comprises:
a synchronization unit for synchronizing said series of routed sync events by said synchronization stage from said producing-end to said consuming-end;
a routing unit for deciding and routing said series sync event into said synchronization stage in said synchronization unit; and
an in-phase mask generator for generating a synchronized event mask signal at a in-phase sync phase.

6. The apparatus according to claim 5, wherein said synchronization unit further comprises:
a general clocked synchronizer stage group for converting a plurality of routed sync events into a plurality of synced events that can be safely sampled by the clock of said consuming-end;
a general pass-through synchronizer stage group for converting a plurality of routed sync events into a plurality of synced events that can be safely sampled by the clock of said consuming-end; and
an in-phase pass-through synchronizer stage group for converting a plurality of routed sync event into a plurality of synced events that can be safely sampled by the clock of said consuming-end.

7. The apparatus according to claim 5, wherein said routing unit further comprises:
a sync phase generator for generating a sync phase indicator signal of said producing-end; and
a sync stage switcher for routing said series of sync events, and dispatching said sync events into said synchronization stage in said synchronization unit.
